(19) United States
(12) Patent Application Publication
(10) Pub. No.: US 2026/0135527 A1
(43) Pub. Date: May 14, 2026

(54) COMMON MODE SUPRESSION IN ANALOG FRONT-END STAGES USING POSITIVELY COUPLED INDUCTORS

(71) Applicant: Marvell Asia Pte Ltd, Singapore (SG)

(72) Inventors: Saman Jafarlou, Mission Viejo, CA (US); Dragos Cartina, Burnaby (CA); Han-Yuan Tan, Santa Clara, CA (US); Vivekananth Gurumoorthy, Fremont, CA (US); Cindra Widya Abidin, Irvine, CA (US)

(73) Assignee: Marvell Asia Pte Ltd, Singapore (SG)

(21) Appl. No.: 19/381,070

(22) Filed: Nov. 6, 2025

Related U.S. Application Data
(60) Provisional application No. 63/718,508, filed on Nov. 8, 2024.

(51) Int. Cl. H03F 3/195; H03F 1/56; H03F 3/45

(52) U.S. Cl. CPC H03F 3/195; H03F 1/565; H03F 3/45475; H03F 3/45632; H03F 2200/451

(57) ABSTRACT

AFE stages using positively coupled inductors and associated systems, components, and devices are disclosed. An example AFE component that may be included in an AFE stage of a system includes a differential circuit comprising a positive signal branch and a negative signal branch. The negative signal branch includes a first input transistor (e.g., a first common-source amplifier) and a first inductor coupled to a source terminal of the first input transistor. The positive signal branch includes a second input transistor (e.g., a second common-source amplifier) and a second inductor coupled to a source terminal of the second input transistor. A coupling coefficient of the first inductor and the second inductor is positive and sufficiently large to ensure that the common-mode impedance of the coupled inductors is greater than their differential-mode impedance.

### CROSS-REFERENCE TO RELATED APPLICATION

This application claims the benefit of U.S. Provisional Patent App. No. 63/718,508, entitled “Common Mode Suppression in CTLE Stages Using Degeneration Tcoil,” filed on Nov. 8, 2024, the disclosure of which is expressly incorporated herein by reference in its entirety.

### BACKGROUND

In high-speed communication systems, analog front-end (AFE) stages play a crucial role in processing signals before they are converted to digital form. Examples of such systems include Optical Circuit Interconnects (OCI) and Co-Packaged Optics (CPO). OCI systems use dedicated optical paths to enable low-latency, high-bandwidth communication between nodes, such as central processing units (CPUs), graphics processing units (GPUs), or field-programmable gate arrays (FPGAs). This setup is particularly beneficial for applications requiring dense optical input/output (I/O) between integrated circuit dies in advanced multi-die packaging, as well as for rack-scale or board-level interconnects in artificial intelligence (AI) clusters and data centers. On the other hand, CPO systems integrate optical transceivers directly alongside switch or processor application-specific integrated circuits (ASICs) to minimize electrical signal loss and reduce energy consumption. This arrangement helps overcome the limitations of electrical I/O, supporting higher aggregate bandwidths while reducing energy per bit.

Common mode suppression is crucial in AFE stages as it significantly enhances the overall performance and stability of the system. In differential signaling, the desired signal is the difference between two complementary signals, and any noise or interference that affects both signals equally is unwanted common mode noise. Common-mode gain refers to the amplification of signals that are common to both inputs of the differential pair. High common-mode gain can amplify unwanted noise in a differential AFE stage, degrading the quality of the differential signal. Common-mode signals can also cause instability in the system. Thus, by suppressing common-mode signals, the system can better preserve the integrity of the differential signal and achieve greater stability and reliability.

### BRIEF DESCRIPTION OF THE DRAWINGS

Embodiments will be readily understood by the following detailed description in conjunction with the accompanying drawings.

FIG. 1 is a block diagram of an example optical communication system in which AFE stages using positively coupled inductors may be implemented, according to an embodiment.

FIGS. 2A-2D illustrate example electric circuit diagrams of AFE components using positively coupled inductors, according to some embodiments.

FIGS. 3A-3C illustrate how positive coupling between inductors may be achieved, according to an embodiment.

FIG. 4 illustrates a top-down view of an integrated circuit (IC) structure, an example layout of metal traces in different layers of a metallization stack to realize a positively coupled inductor arrangement, according to an embodiment.

### DETAILED DESCRIPTION

AFE stages using positively coupled inductors and associated systems, components, and devices are disclosed. The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating AFE stages using positively coupled inductors, described herein, it might be useful to first understand phenomena that may come into play in some systems where AFE stages may be used. The following foundational information may be viewed as a basis from which the present disclosure may be properly explained. Such information is offered for purposes of explanation only and, accordingly, should not be construed in any way to limit the broad scope of the present disclosure and its potential applications.

AFE stages frequently employ common source amplifiers. Common source amplifiers are a type of electronic amplifier where the input signal is applied to the gate terminal, and the output is taken from the drain terminal. These amplifiers often use degeneration impedances, which are resistors or inductors placed in the source terminal to stabilize the amplifier and introduce a zero in the transfer function, improving the frequency response. Common source amplifiers may, e.g., be used in Continuous-Time Linear Equalizers (CTLEs), which are circuits typically implemented in AFE stages and used to compensate for signal loss and distortion in high-speed communication systems.

A common source amplifier can be implemented as part of a differential amplifier configuration. In a differential amplifier, each half of the circuit (i.e., a positive signal branch half and a negative signal branch half) may include a common source amplifier. Each half of the circuit may be biased by its own tail current source. A tail current source is a current source connected to the common source node of a differential pair, providing a constant current. Using two separate tail current sources results in a pseudo-differential configuration, which means the circuit behaves like a differential amplifier but with some differences in performance.

A pseudo-differential configuration may help achieve the desired amplification and frequency response characteristics while managing the common-mode gain and stability issues. However, this configuration may also lead to high common-mode gain which can negatively impact the common mode rejection ratio (CMRR). CMRR refers to the ability of the amplifier to reject common-mode signals (signals that are the same on both inputs). Poor CMRR can cause common mode instability, where the amplifier becomes unstable due to common-mode signals.

Additionally, having degenerative capacitance at the source provides negative resistance. Degenerative capacitance is a capacitor coupled to a source terminal of an amplifier (e.g., a transistor) to improve stability and bandwidth. Negative resistance (positive common mode S11) seen at the input bumps can cause instability at the input. S11 is a parameter that measures the reflection coefficient at the input, and positive common mode S11 indicates instability.

Conventional approaches to suppressing S11 parameters in such circuits include adjusting the degenerative values of a tunable RC circuit coupled between positive and negative branches of a differential amplifier. While these approaches may help mitigate the issue of positive common mode S11, they result in suboptimal differential performance. Differential performance refers to the amplification of the difference between the two input signals, which is the desired operation of the differential amplifier.

As the foregoing illustrates, reducing the common-mode gain of differential circuits employing common source amplifiers, used in AFE stages of various systems, while minimally affecting the differential performance remains a formidable challenge, despite the attractive benefits of such circuits. Embodiments of the present invention are based on recognition that employing AFE stages with positively coupled inductors may help achieve common mode suppression to enhance performance, stability, and reliability of high-speed communication systems by minimizing the impact of unwanted common-mode signals while preserving the desired differential signal performance. In particular, coupled inductors may be introduced at the source terminals of the input transistors of an AFE stage component using common source amplifiers in a differential configuration. Coupled inductors can increase the source impedance, thereby degenerating the stage by the impedance seen into the inductors. The advantage of using coupled inductors is that their impedance can differ between common mode and differential mode. Selecting a sufficiently large positive coupling coefficient for the coupled inductors may allow achieving a relatively high common-mode impedance to enhance stability while simultaneously ensuring a relatively low differential-mode impedance to minimize impacts on differential performance.

In one aspect, an example AFE component that may be included in an AFE stage of a system includes a differential circuit comprising a positive signal branch and a negative signal branch. The negative signal branch includes a first input transistor (e.g., a first common-source amplifier) and a first inductor coupled to a source terminal of the first input transistor. The positive signal branch includes a second input transistor (e.g., a second common-source amplifier) and a second inductor coupled to a source terminal of the second input transistor. A coupling coefficient of the first inductor and the second inductor is positive and sufficiently large to ensure that the common-mode impedance of the coupled inductors is greater than their differential-mode impedance.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

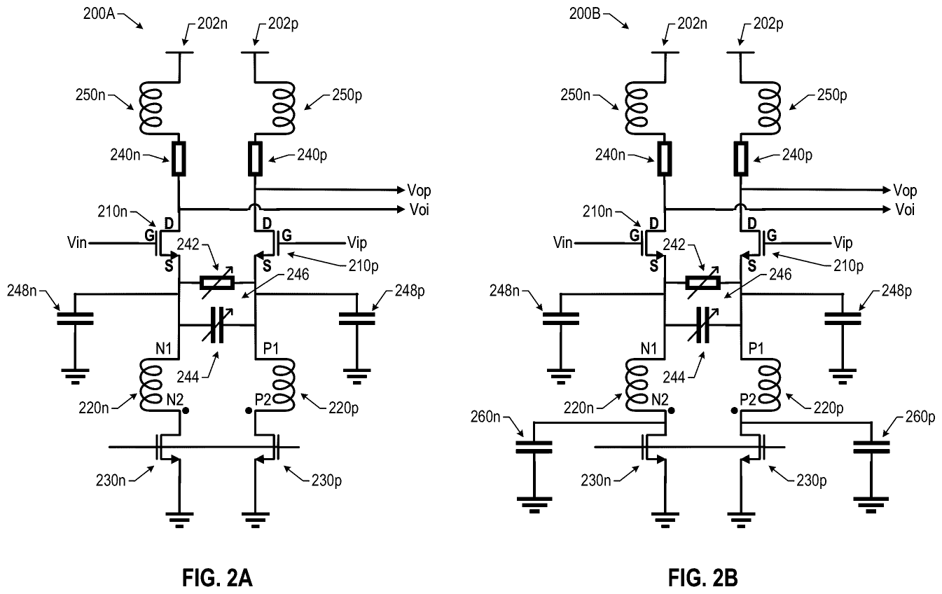

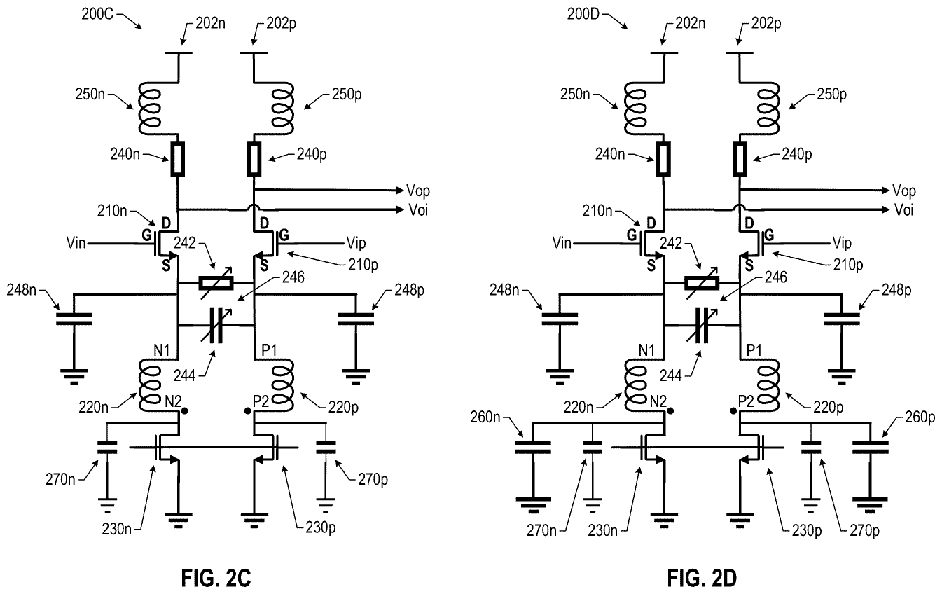

Any of the features discussed with reference to any accompanying drawings herein may be combined with any other features to form an optical communication system 100, any of the AFE components 200, or any of positively coupled inductor arrangements 300 or 400, as appropriate. For convenience, letters A, B, C, etc., used after a reference numeral may be used to refer to different instances of similar elements. For example, the term “AFE component 200” may be used to refer to one of the AFE components 200A, 200B, 200C, or 200D shown in FIGS. 2A-2D. Also for convenience, a collection of drawings identified with letters in their figure numbers may be referred to without the letters, e.g., a collection of FIGS. 2A-2D may be referred to as “FIG. 2.” A number of elements of the drawings with same reference numerals may be shared between different drawings; for ease of discussion, a description of these elements provided with respect to one of the drawings is not repeated for the other drawings, and these elements may take the form of any of the embodiments disclosed herein.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10%, e.g., within +/−5% or within +/−2%, of the exact orientation.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, the terms “package” and “integrated circuit (IC) package” are synonymous, as are the terms “die” and “IC die.” Furthermore, the terms “chip,” “chiplet,” “die,” and “IC die” may be used interchangeably herein.

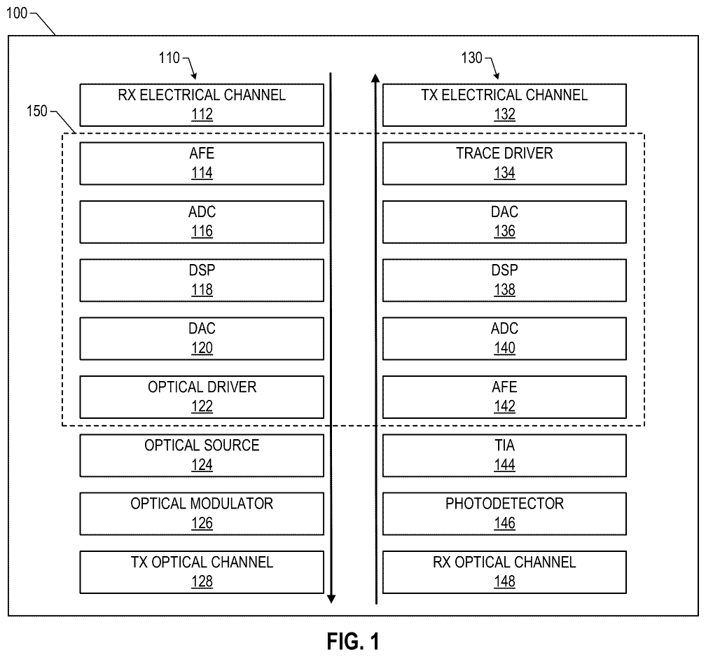

FIG. 1 is a block diagram of an example optical communication system 100 in which AFE stages using positively coupled inductors may be implemented, according to an embodiment. The left column of FIG. 1 illustrates components of a transmitter (TX) module 110, while the right column illustrates components of a receiver (RX) module 130 of the optical communication system 100. As shown in FIG. 1, the TX module 110 may include, from top to bottom, an RX electrical channel 112, an AFE 114, an analog-to-digital converter (ADC) 116, a digital signal processor (DSP) 118, a digital-to-analog converter 120, an optical driver 122, an optical source 124, an optical modulator 126, an a TX optical channel 128. As further shown in FIG. 1, the RX module 110 may include, from top to bottom, a TX electrical channel 132, a trace driver 134, a DAC 136, a DSP 138, an ADC 140, an AFE 142, a transimpedance amplifier (TIA) 144, a photodetector 146, and an RX optical channel 148. In FIG. 1, the direction of the signal flow in the TX module 110 is shown with an arrow on the right side of the TX module 110, indicating that the signals may flow from the top to the bottom of the components of the TX module 110 as shown in FIG. 1 (e.g., from the RX electrical channel 112 to the TX optical channel 128). Similarly, the direction of the signal flow in the RX module 130 is shown with an arrow on the left side of the RX module 130, indicating that the signals may flow from the bottom to the top of the components of the RX module 130 as shown in FIG. 1 (e.g., from the RX optical channel 148 to the TX electrical channel 132).

At a functional level, the optical communication system 100 may operate by receiving electrical signals at the RX electrical channel 112 of the TX module 110, converting these signals into modulated optical signals, transmitting the optical signals through the TX optical channel 128, and reconverting the received optical signals back into electrical signals at the RX module 130. Additional embodiments may incorporate advanced modulation formats, digital signal processing, and error correction to further enhance performance and reliability across different deployment environments.

Starting with the details of the TX module 110, the RX electrical channel 112 may be any suitable electrical channel for receiving electrical signals from a host and transmitting the signals to the TX module 110. The RX electrical channel 112 may serve as the entry point for the signals into the TX module 110. In some embodiments, the RX electrical channel 112 may include metal interconnects (e.g., copper interconnects) for supporting propagation of electrical signals.

The AFE 114 may include any suitable circuitry for amplifying and conditioning the incoming electrical signals from the RX electrical channel 112. The AFE 114 may prepare the signals for conversion by the ADC 116, e.g., ensuring that they are within the appropriate voltage range and have the necessary signal integrity. In some embodiments, the AFE 114 may include positively coupled inductors as described herein. For example, in some embodiments, the AFE 114 may include a differential amplifier with an input transistor in each of a positive signal branch and a negative signal branch of the circuit, and with positively coupled inductors coupled to the source terminals of the input transistors. In some embodiments, positively coupled inductors may be part of a CTLE that may be included in the AFE 114.

The ADC 116 may include any suitable circuitry for converting the conditioned analog signals output by the AFE 114 into digital signals. In various embodiments, the ADC 116 may include one of more of flash ADCs, successive approximation register (SAR) ADCs, delta-sigma ADCs, pipeline ADCs, integrating ADCs, time-interleaved ADCs, etc. Digital signals output by the ADC 116 may be provided to the DSP 118 for digital signal processing, allowing the system to manipulate and analyze the data in a digital format.

The DSP 118 may include any suitable circuitry for performing various signal processing tasks on the digital signals received from the ADC 116, such as filtering, modulation, and error correction, to optimize transmission quality. For example, the DSP 118 may implement impedance matching and signal conditioning to ensure compatibility with downstream driver circuitry (e.g., with the optical driver 122). In addition, the DSP 118 may incorporate equalization techniques such as pre-emphasis or de-emphasis to compensate for frequency-dependent losses in the electrical interconnect path. In some embodiments, the DSP 118 may also provide clock-data recovery (CDR), retiming, and multiplexing to align and stabilize the signal prior to modulation. In certain embodiments, the DSP 118 may implement forward error correction (FEC) encoding, scrambling, and other coding schemes to improve link robustness and reduce bit error rate (BER). Furthermore, the DSP 118 may perform modulation mapping (e.g., NRZ, PAM-4, or other advanced modulation formats) to prepare data streams for optical modulation. Overall, the DSP 118 may serve as a bridge between the high-speed digital data domain and the analog driver circuitry, ensuring that the transmitted signal has sufficient integrity, spectral efficiency, and resilience against noise and channel impairments for reliable conversion into optical signals. The DSP 118 may enhance the quality and reliability of the signals before they are converted back to analog form by the DAC 120.

The DAC 120 may include any suitable circuitry for converting the digital signals processed by the DSP 119 back into analog signals for driving optical components of the TX module 110 using the optical driver 122. In various embodiments, the DAC 120 may include one of more of binary-weighted DACs, current-steering DACs, charge-redistribution DACs, delta-sigma DACs, and so on.

The optical driver 122 may include any suitable circuitry for amplifying the analog signals output by the DAC 120 to a level suitable for driving an optical component such as the optical source 124 or the optical modulator 126. The optical driver 122 may ensure that the signals have sufficient power to be transmitted over the TX optical channel 128. The optical driver 122 may be designed to meet stringent requirements for bandwidth, output swing, linearity, noise performance, and energy efficiency. In some embodiments, the driver may be implemented as a differential driver. The optical driver 122 may also incorporate impedance matching networks to ensure efficient power transfer and minimize signal reflections at high frequencies. In various implementations, the optical driver 122 may include pre-emphasis, feed-forward equalization (FFE), or other analog equalization techniques to mitigate channel-induced distortion, compensate for parasitic effects, and preserve signal fidelity. Advanced embodiments may also support programmable drive strength or adaptive biasing to balance performance and power consumption across different operating conditions. The optical driver 122 may function as an interface between the electronic DSP domain and the optical modulation stage, ensuring that high-speed data signals are properly translated into robust modulation of the optical carrier

The optical source 124 may include any suitable device configured to generate and emit electromagnetic radiation in the optical or microwave portions of the electromagnetic spectrum (such radiation referred to herein as “optical signals” or, simply, “light”). The optical source 124 may be designed to emit light in a controlled, stable, and efficient manner to satisfy the performance requirements of the optical communication system 100. In some embodiments, the optical source 124 may comprise a substantially coherent and monochromatic light source, such as a laser, capable of producing light with a well-defined wavelength, narrow linewidth, low divergence, and high brightness. In some embodiments, the optical source 124 may include a plurality of such light sources of different wavelengths. In some embodiments, the optical source 124 may comprise a multi-wavelength source, such as a laser array, enabling wavelength-division multiplexing (WDM) for higher aggregate data throughput. Examples of lasers that may be employed include semiconductor-based lasers, such as distributed Bragg reflector (DBR) lasers, distributed feedback (DFB) lasers, edge-emitting lasers, and vertical-cavity surface-emitting lasers (VCSELs). Depending on the architecture, the optical source 124 may be configured to deliver unmodulated output (e.g., unmodulated continuous-wave (CW) output) or directly modulated output. In case of the former, the optical source 124 may generate an unmodulated CW optical signal, commonly referred to as an “optical carrier,” which is subsequently modulated by the optical modulator 126 to encode data. In such embodiments, the optical modulator 126 may be driven by the optical driver 122. In case of the latter, the optical source 124 itself may be directly modulated, such that its output intensity or phase varies in accordance with the input electrical signal. In such implementations, the optical source 124 may be driven by the optical driver 122, which provides the necessary high-speed drive signals to encode data. Direct modulation can simplify system architecture by eliminating the need for a separate modulator. In some embodiments, the optical source 124 may further incorporate thermal tuning, current injection, or microelectromechanical (MEMS)-based wavelength control to ensure spectral stability and alignment with channel grids. Advanced embodiments may also integrate power monitoring and feedback loops to maintain output stability under varying operating conditions, thereby enhancing the overall reliability of the optical communication system 100.

The optical modulator 126 may include any suitable component configured to modulate or alter one or more properties of an optical signal, such as an optical carrier emitted by the optical source 124, in order to encode information onto the signal and/or perform various signal processing functions. The optical modulator 126 may modulate the optical signal based on an electrical input, such as that provided by the optical driver 122. Depending on system requirements for integration, bandwidth, and modulation format, the optical modulator 126 may include, for example, one or more Mach-Zehnder modulators (MZMs), electro-absorption modulators (EAMs), or micro-ring modulators (MRMs).

The TX optical channel 128 may include any suitable optical transmission medium in the form of one or more light-guiding structures, such as optical fibers or waveguides, configured to control and direct the propagation of modulated optical signals from the TX module 110 to the RX module 130. These light-guiding components may take the form of planar waveguides, photonic crystal waveguides, rib waveguides, or conventional optical fibers, all designed to confine light and guide it along predetermined paths with minimal loss, dispersion, or cross-talk. In some embodiments, the TX optical channel 128 may employ a core material with a higher refractive index surrounded by a cladding material of lower refractive index. This refractive index contrast may confine light within the core via total internal reflection, allowing efficient propagation over distances. Depending on system requirements, the TX optical channel 128 may support single-mode or multimode propagation and may also incorporate wavelength-division multiplexing (e.g., WDM or dense WDM (DWDM)) techniques to increase channel capacity through multiple optical carriers.

Turning to the details of the RX module 130, the RX optical channel 148 may include any suitable optical transmission medium to control and direct the propagation of modulated optical signals from the TX module 110 to the RX module 130. Descriptions of various light-guiding components provided with respect to the TX optical channel 128 are applicable to the RX optical channel 148.

The photodetector 146 may include any suitable circuitry for converting the incoming optical signals into electrical signals, such as photocurrent. The photodetector 146 may detect the light signals received at the RX optical channel 148 and generate corresponding electrical signals for further processing. Depending on the application requirements, the photodetector 146 may comprise a variety of suitable devices, including PIN photodiodes, avalanche photodiodes (APDs), phototransistors, CMOS image sensors, photomultiplier tubes, or quantum photodetectors. Selection of the photodetector type may depend on factors such as bandwidth, responsivity, sensitivity, linearity, and noise performance. The photodetector 146 may be designed to support the bandwidth of the incoming modulated optical signal received at the RX optical channel 148 while preserving signal fidelity for downstream processing.

The TIA 144 may include any suitable circuitry for amplifying the relatively weak electrical signals generated by the photodetector 146 and converting the photocurrent into a voltage signal suitable for further processing. In some embodiments, the TIA 144 may be designed to optimize the trade-off between gain and bandwidth and may incorporate features such as noise filtering, input impedance matching, and automatic gain control (AGC) to maintain signal integrity across varying input conditions.

The AFE 142 may include any suitable circuitry for amplifying and conditioning the incoming electrical signals from the TIA 144. The AFE 142 may prepare the signals for conversion by the ADC 140, e.g., ensuring that they are within the appropriate voltage range and have the necessary signal integrity. Similar to the AFE 114, in some embodiments, the AFE 142 may include positively coupled inductors as described herein. For example, in some embodiments, the AFE 142 may include a differential amplifier with an input transistor in each of a positive signal branch and a negative signal branch of the circuit, and with positively coupled inductors coupled to the source terminals of the input transistors. In some embodiments, positively coupled inductors may be part of a CTLE that may be included in the AFE 142.

The ADC 140 may include any suitable circuitry for converting the conditioned analog signals output by the AFE 142 into digital signals. Descriptions of various types of the ADC 116 are applicable to the ADC 140. Digital signals output by the ADC 140 may be provided to the DSP 138 for digital signal processing, allowing the system to manipulate and analyze the data in a digital format.

The DSP 138 may include any suitable circuitry for performing various signal processing tasks on the digital signals received from the ADC 140, such as filtering, demodulation, and error correction, to optimize reception quality. For example, the DSP 138 may implement impedance matching and signal conditioning to ensure compatibility with upstream receiver circuitry (e.g., with the DAC 136). In addition, the DSP 138 may incorporate equalization techniques such as feed-forward equalization (FFE) or decision feedback equalization (DFE) to compensate for inter-symbol interference (ISI) and other channel-induced distortions introduced during optical transmission from the TX module 110. In some embodiments, the DSP 138 may also provide CDR, retiming, and multiplexing to align and stabilize the signal prior to further processing by the RX module 130. In certain embodiments, the DSP 138 may implement FEC decoding, descrambling, and other decoding schemes to improve link robustness and reduce BER. Furthermore, the DSP 138 may perform demodulation mapping (e.g., NRZ, PAM-4, or other advanced modulation formats) to decode data streams received from optical signals. Overall, the DSP 138 may serve as a bridge between the high-speed digital data domain and the analog receiver circuitry, ensuring that the received signal has sufficient integrity, spectral efficiency, and resilience against noise and channel impairments for reliable conversion into electrical signals. The DSP 138 may enhance the quality and reliability of the signals before they are converted back to analog form by the DAC 136.

The DAC 136 may include any suitable circuitry for converting the processed digital signals output by the DSP 138 back into analog signals. Descriptions of various types of the DAC 120 are applicable to the DAC 136. Analog signals output by the DAC 136 may be provided to the trace driver 134.

The trace driver 134 may include any suitable circuitry for amplifying the analog signals to a level suitable for driving the TX electrical channel 132. The trace driver 134 may ensure that the signals have sufficient power to be transmitted over the TX electrical channel 132.

The TX electrical channel 132 may be any suitable electrical channel for receiving electrical signals from the RX module 130 and transmitting the signals to the host. The TX electrical channel 132 may represent the electrical path through which the amplified analog signals are transmitted. It serves as the medium for carrying the electrical signals to the external destination (e.g., the host). The TX electrical channel 132 may serve as the exit point for the signals from the RX module 130. In some embodiments, the TX electrical channel 132 may include metal interconnects (e.g., copper interconnects) for supporting propagation of electrical signals.

FIG. 1 further illustrates a dashed box 150 indicating components which may be implemented on a single chip. Such a chip may be referred to as a DSP chip in some implementations and may include the AFE 114, the ADC 116, the DSP 118, the DAC 120, the optical driver 122, the trace driver 134, the DAC 136, the DSP 138, the ADC 140, and the AFE 142. In other embodiments, the optical driver 122 may be external to the DSP chip.

FIG. 1 depicts several components of the optical communication system 100; however, depending on the implementation, one or more of these components may be omitted, replicated, or otherwise modified to suit the particular application. In certain embodiments, some or all of the illustrated components may be mounted on one or more motherboards or other suitable support structures. In other embodiments, some or all of the components may be integrated into a single system-on-chip (SoC) die. Furthermore, in some implementations, the optical communication system 100 may exclude one or more of the components shown in FIG. 1 and instead employ interface circuitry configured to couple to such components externally. For example, the optical communication system 100 may not include an optical source 124, but may include interface circuitry (e.g., a connector) to which an optical source 124 may be coupled.

Other components may be present in the optical communication system 100 besides those shown in FIG. 1. Examples of such other components include a serializer/deserializer (SerDes), digital predistortion (DPD) circuitry, a power management integrated circuit (PMIC), optical coupling interfaces, an optical amplifier, or various passive components, described below.

A SerDes of the optical communication system 100 may be configured to convert parallel data streams into serial data streams for transmission over high-speed interfaces, or to perform the reverse operation on received data. By converting between parallel and serial formats, the SerDes may facilitate efficient high-bandwidth data transfer between electronic processing units and the optical communication system 100. The SerDes may further include features such as CDR, word alignment, and de-skewing to maintain signal integrity across the interface. In some embodiments, the SerDes may be integrated with the DSP 118 and/or DSP 138, providing a tightly coupled interface between digital processing and optical transmission.

DPD circuitry of the optical communication system 100 may be configured to apply pre-compensation to electrical signals prior to their conversion into optical signals by the optical driver 122 and optical modulator 126 in case of external modulation, or by the optical driver 122 and the optical source 124 in case of directly modulated optical signals. By intentionally shaping or modifying the input signals, the DPD circuitry may be able to counteract known nonlinearities, distortions, and frequency-dependent impairments present in the optical driver, modulator, or transmission path. This may result in improved linearity, reduced signal distortion, and enhanced overall fidelity of the modulated optical signal. In various embodiments, the DPD circuitry may operate in the digital domain within the DSP 118 or as a separate processing block. The DPD algorithms may be adaptive, continuously adjusting to changes in system characteristics such as temperature, aging, or component variability, thereby maintaining optimal signal quality over time. By compensating for distortions before transmission, the DPD circuitry can improve the BER, increase achievable data rates, and support higher-order modulation formats in the optical communication system 100.

A PMIC of the optical communication system 100 may comprise any suitable controller, such as a microcontroller, configured to manage and regulate the operation of various components within the optical communication system 100. In certain embodiments, the PMIC may provide feedback-controlled biasing for the optical source 124 and/or the optical modulator 126, helping achieve stable performance across temperature variations and over the device lifetime. To achieve this, the PMIC may include bias circuitry capable of applying a controlled DC voltage or current to establish the optimal operating point of the optical source and/or modulator. The PMIC may also integrate monitoring photodiodes and control loops to dynamically adjust the bias based on real-time output measurements. In some embodiments, the PMIC may be located within the TX module 110, the RX module 130, or both.

An optical coupling interface may be present between the optical modulator 126 and the TX optical channel 128 to achieve efficient light transfer between the two. Such an optical coupling interface may include a variety of coupling mechanisms, such as fiber couplers (e.g., fused or tapered fiber couplers), waveguide couplers, grating couplers, edge couplers, lens-based couplers, microlens arrays, prism couplers, fiber array couplers, or ball lens couplers. These components may be designed to ensure minimal insertion loss and efficient optical alignment between the TX module 110 and the TX optical channel 128. A similar optical coupling interface may be present between the RX optical channel 148 and the photodetector 146.

An optical amplifier of the optical communication system 100 may be configured to directly amplify an optical signal without first converting it to an electrical signal. Such amplification can be used to boost optical power within a waveguide or fiber, for example in the TX optical channel 128 or RX optical channel 148, helping maintain signal strength and quality over long distances or through lossy components. In some embodiments, an optical amplifier may include a semiconductor optical amplifier (SOA). In other embodiments, it may include alternative types of optical amplifiers, such as erbium-doped fiber amplifiers (EDFAs), Raman amplifiers, or hybrid/integrated amplifiers combining SOAs with other photonic elements. An optical amplifier may be incorporated into any or all of the TX module 110, RX module 130, and optical transmission subsystem between the TX module 110 and the RX module 130.

Various passive optical components may be included in the optical communication system 100. Such passive optical components may include elements such as multiplexers, demultiplexers, periodic optical filters, splitters, or ring resonators. These components may be configured to manage optical signal routing, separate or combine wavelengths, suppress undesired spectral components, and generally facilitate precise control over optical paths within the optical communication system 100.

In certain embodiments, the optical communication system 100 may function as an OCI system, providing high-speed, low-latency, and energy-efficient data transfer between nodes (e.g., various electronic processing units) via an optical transmission medium. Such processing units may include, for example, CPUs, GPUs, or FPGAs. In some applications, the optical communication system 100 may be employed for chip-to-chip or chiplet-level interconnects, thereby enabling dense optical I/O between integrated circuit dies in advanced multi-die packaging. In other scenarios, the optical communication system 100 may be used for rack-scale or board-level interconnects, such as replacing traditional copper links in AI clusters and data centers with optical fibers in order to reduce power consumption and improve bandwidth scalability. In yet other applications, the optical communication system 100 may be configured for CPO, where optical transmitters and receivers are integrated in close proximity to switching units (e.g., ASICs) in data center switches. This arrangement may help overcome limitations of electrical I/O, thereby supporting higher aggregate bandwidths while reducing energy per bit.

In some embodiments, the optical communication system 100 may incorporate a photonic integrated circuit (PIC). A PIC may be a miniaturized, integrated optical device that combines multiple photonic components, such as optical modulators, photodetectors, and waveguides, onto a single substrate. For example, a PIC may include one or more optical modulators 126 to encode data onto optical signals generated by the optical source 124. In another example, a PIC may include one or more photodetectors 146 to detect and measure light intensity across various wavelengths by converting incident photons into electrical signals. Additionally, a PIC may integrate one or more waveguides, which may include any of the waveguide structures described with reference to the TX optical channel 128 or other portions of the optical communication system 100. By integrating multiple photonic functions on a single substrate, the PIC can reduce footprint, improve signal integrity, and enable scalable, high-performance optical communication.

FIGS. 2A-2D illustrate example electric circuit diagrams of AFE components 200 using positively coupled inductors, according to some embodiments. Any of the AFE components 200 of FIGS. 2A-2D may be implemented as part of the AFE 114, the AFE 142, or both. In some embodiments, the AFE 114 and the AFE 142 may include different embodiments of the AFE components 200; e.g., the AFE 114 may include an AFE component 200A as shown in FIG. 2A, while the AFE 142 may include an AFE component 200B as shown in FIG. 2B. Implementations of the AFE components 200 are not limited to the optical communication system 100 as shown in FIG. 1 or to an optical communication system at all. In some embodiments, any of the AFE components 200 may be a part of an AFE stage of a communication system other than an optical communication system. For example, any of the AFE components 200 may be a part of an AFE stage of a radio frequency (RF) communication system or a satellite communication system. In some embodiments, any of the AFE components 200 may be a part of an AFE stage of a system other than a communication system. For example, any of the AFE components 200 may be a part of an AFE stage of a light detection and ranging (LiDAR) system, an automotive system/device, a medical imaging system/device, an industrial automation system/device, or a consumer electronics system/device (e.g., a mobile phone, a tablet, a smart watch, or a laptop).

Each of FIGS. 2A-2D illustrates transistors as field-effect transistors (FETs) using their conventional representation in electric circuit diagrams where, to assist explanations, gate, source, and drain terminals of such transistors are labeled with the letters G, S, and D, respectively. Conventional representation in electric circuit diagrams is also used in FIGS. 2A-2D to illustrate that the FETs may be N-type FETs. However, the designation of the N-type and P-type transistors of FIGS. 2A-2D may be reversed if ground and supply voltages are reversed, these embodiments also being within the scope of the present disclosure. In addition, FIGS. 2A-2D illustrates resistors, inductors, and capacitors using standard schematic symbols. The first and second terminals of these passive components are not specifically labeled in order to reduce visual clutter and improve readability of the diagrams. FIGS. 2A-2D collectively demonstrate various possible configurations of transistors and other elements that may be incorporated into AFE stages with positively coupled inductors.

Each of FIGS. 2A-2D illustrates a differential implementation, in which pairs of transistors, passive components, and interconnects are arranged to process complementary electrical signals. In a differential configuration, two signals are transmitted simultaneously but along two separate signal branches (or paths): one carrying the positive polarity of the information (referred to herein as a “positive signal branch” and labeled in the drawings with a letter “p”) and the other carrying the inverse (negative) polarity (referred to herein as a “negative signal branch” and labeled in the drawings with a letter “n”). The receiving stage responds to the voltage difference between the two signals, rather than to the absolute voltage of a single signal referenced to ground. Such an arrangement may provide multiple advantages, including enhanced common-mode noise rejection, improved immunity to supply and substrate noise, reduced sensitivity to crosstalk, and improved linearity in high-speed operation.

FIG. 2A illustrates an electric circuit diagram of an AFE component 200A, according to an embodiment. The AFE component 200A may be an example of the AFE 114 and the AFE 142 (or a part thereof), or may be a part of an AFE stage of a communication system other than an optical communication system or may be part of an AFE stage of a system other than a communication system.

As shown in FIG. 2A, the AFE component 200A may include a negative signal branch 202n and a positive signal branch 202p. An individual signal branch 202 may include an amplifier 210 and an inductor 220 coupled (e.g., directly electrically connected) to the amplifier 210, and may further, optionally, include one or more of a current source 230, a resistor 240 and a further inductor 250, each denoted in FIG. 2A with a letter “n” after the reference numeral for the negative signal branch 202n and with a letter “p” after the reference numeral for the positive signal branch 202p. The AFE component 200A may have input terminals Vi and output terminals Vo, where the input terminals Vi are labeled in FIG. 2A as an input terminal Vin for the positive signal branch 202p and as an output terminal Vip for the negative signal branch 202n, and, similarly, the output terminals Vo are labeled in FIG. 2A as an output terminal Vop for the positive signal branch 202p and as an output terminal Von for the negative signal branch 202n. In an individual signal branch 202, each of the amplifier 210 and the current course 230 may be implemented as a transistor, as illustrated in FIG. 2A.

As further shown in FIG. 2A, the AFE component 200A may include a resistor 242 and a capacitor 244 coupled between the negative signal branch 202n and the positive signal branch 202p. One or both of the resistor 242 and the capacitor 244 may be tunable. First terminals of the resistor 242 and the capacitor 244 may be coupled (e.g., directly electrically connected) to a node between the amplifier 210n and the inductor 220n of the negative signal branch 202n (e.g., to a source terminal of the amplifier 210n and to a terminal N1 of the inductor 220n), while second terminals of the resistor 242 and the capacitor 244 may be coupled (e.g., directly electrically connected) to a node between the amplifier 210p and the inductor 220p of the positive signal branch 202p (e.g., to a source terminal of the amplifier 210p and to a terminal P1 of the inductor 220p). Thus, the resistor 242 and the capacitor 244 may be in electrical parallel with one another, forming a RC circuit 246. The RC circuit 246 may help achieve the desired amplification and frequency response characteristics while managing common-mode gain and stability issues, especially when the values of the resistor 242 and/or the capacitor 244 are tunable. However, presence of the RC circuit 246 may also lead to undesirable parasitic capacitance at the source terminals of the amplifiers 210n and 210p, represented in FIG. 2A as capacitors 248n and 248p, for the negative and positive signal branches 202n and 202p, respectively.

Parasitic capacitance in IC structures (e.g., as represented by the capacitors 248n and 248p) is undesirable because it slows down signal transitions, increases dynamic power consumption, and degrades both digital and analog performance. Furthermore, having degenerative capacitance, in the form of the capacitor 244 and/or the parasitic capacitor 248, at the source terminal of the amplifiers 210, may provide undesirable negative resistance (positive common mode S11 parameter) seen at the input terminals Vin and Vip (i.e., negative input resistance), which can cause instability at the input. In addition, using two separate tail current sources 230n and 230p results in a pseudo-differential configuration that may lead to high common-mode gain, negatively impacting performance of the AFE component 200A (e.g., resulting in poor CMRR). Presence of the coupled inductors 220n and 220p in the AFE component 200A, particularly when the inductors 220n and 220p are arranged to be positively coupled inductors, may help alleviate one or more of these issues.

In an individual signal branch 202, the amplifier 210 may be implemented as a transistor, as illustrated in FIG. 2A (e.g., each of the amplifiers 210n and 210p may be a common source amplifier). In such embodiments, in each signal branch 202, a gate terminal of the transistor 210 of the branch may be coupled (e.g., directly electrically connected) to an input terminal Vi of the branch, while a drain terminal of the transistor 210 of the branch may be coupled (e.g., directly electrically connected) to an output terminal Vo of the branch. A source terminal of the transistor 210 of the branch may be coupled (e.g., directly electrically connected) to a corresponding first terminal of the inductor 220 of the branch. The second terminals of the inductors 220 in each of the branches 202 may be coupled (e.g., directly electrically connected) to the respective current sources 230. Thus, for the negative signal branch 202n, the gate terminal of the transistor 210n may be coupled to the input terminal Vin, the drain terminal of the transistor 210n may be coupled to the output terminal Von, the source terminal of the transistor 210n may be coupled to the terminal N1 of the inductor 220n, and the terminal N2 of the inductor 220n may be coupled to the current source 230n (e.g., to the drain terminal of the transistor of the current source 230n). Similarly, for the positive signal branch 202p, the gate terminal of the transistor 210p may be coupled to the input terminal Vip, the drain terminal of the transistor 210p may be coupled to the output terminal Vop, the source terminal of the transistor 210p may be coupled to the terminal P1 of the inductor 220p, and the terminal P2 of the inductor 220p may be coupled to the current source 230p (e.g., to the drain terminal of the transistor of the current source 230p). The drain terminals of the current sources 230n and 230p may be coupled to ground, as shown in FIG. 2A.

Embodiments of the present disclosure are based on recognition that adding the inductors 220 at the source terminals of the amplifiers 210 can, advantageously, make input resistance positive at frequencies lower than LC resonance. The impedance of the coupled inductors 220 differs in common and differential modes, and this property can be exploited to maintain a high common-mode impedance (Lcm) for suppressing common-mode signals while keeping the differential-mode impedance (Ldm) low to preserve differential performance, provided that the coupling coefficient of the inductors 220 is positive and sufficiently large. This may be explained as follows. For a simplified case where inductance of the inductors 220n and 220p is the same, Lcm may be calculated as Lcm=2L(1−k), where L is the inductance of the inductors 220 n and 220p, k is the coupling coefficient between the inductors 220 n and 220 p, and the value of k may be any number between −1 and 1. On the other hand, Ldm may be calculated as Ldm=½L(1+k). From these two formulas it follows that, when the coupling coefficient k is negative, the value of the Ldm steadily increases while the value of the Lcm steadily decreases as the absolute value of the coupling coefficient increases. Having a negative coupling coefficient k is, therefore, undesirable because it prevents achieving a relatively high Lcm with a relatively low Ldm. In contrast, when the coupling coefficient k is positive, the value of the Ldm steadily decreases while the value of the Lcm steadily increases as the value of the coupling coefficient increases. When k=0.6, the Ldm is equal to the Lcm, and for values of k greater than 0.6, the Ldm is, advantageously, smaller than the Lcm. Although the exact formulas for Lcm and Ldm change when the inductances of the inductors 220n and 220p are not equal, the same trend holds. Thus, by selecting a sufficiently high positive coupling coefficient (e.g., above about 0.6 in the simplified equal-inductance case), the difference between Lcm and Ldm can be enhanced. In practice, this enables achieving a relatively high Lcm to improve stability of the AFE component 200A while maintaining a relatively low Ldm to minimize impact on the differential performance of the AFE component 200A.

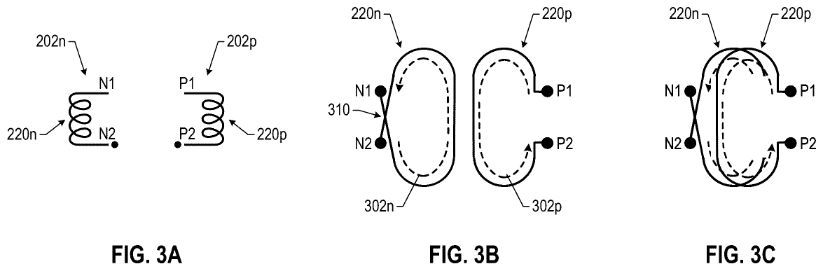

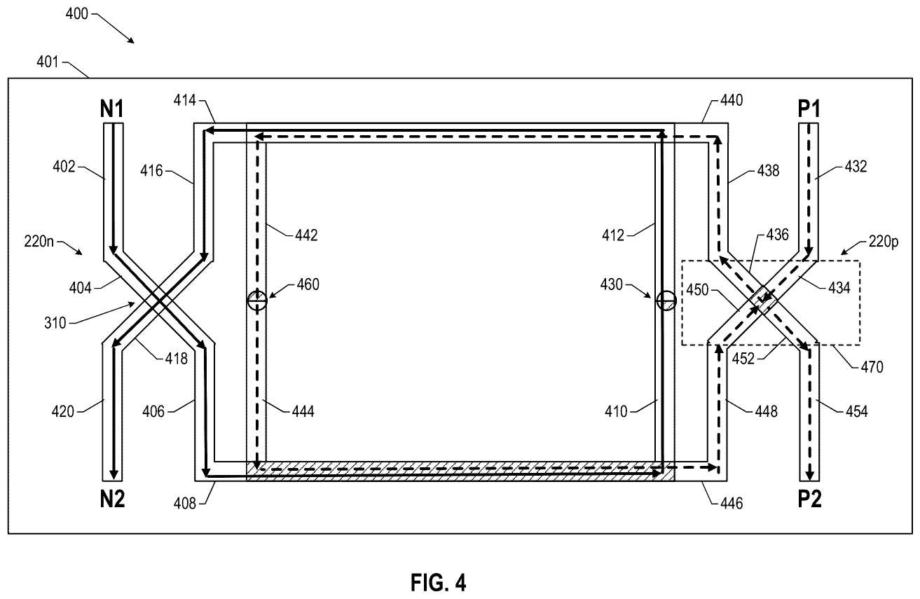

In accordance with the convention, dots are used at the terminals of the inductors 220 to indicate the terminals where the current exits the coil of the inductors 220. Thus, in the AFE component 200A, the current may exit the inductor 220n at terminal N2 and may exit the inductor 220p at terminal P2. With this configuration, careful arrangement of the inductors 220n and 220p (e.g., arranging their shapes and winding directions) in an IC structure that implements the AFE component 200A can ensure that their coupling coefficient is positive. Furthermore, because the coupling coefficient k is defined as the ratio of the mutual inductance M between inductors 220n and 220p to the square root of the product of their individual inductances, its value can be increased either by maximizing mutual inductance or by minimizing unnecessary increases in self-inductance. Accordingly, the physical arrangement of the inductors 220n and 220p may further be optimized to strengthen magnetic coupling and thereby increase the coupling coefficient. Such optimization may involve, for example, reducing the spacing between the inductors 220, aligning them to maximize overlapping magnetic flux, or employing geometries that favor stronger field interaction. These aspects, along with specific layout strategies for achieving higher coupling efficiency, are described in greater detail below with reference to FIGS. 3 and 4.

Further illustrated in FIG. 2A are optional resistors 240 and inductors 250 in each of the signal branches 202. For each of the signal branches 202, as shown, the first terminal of the resistor 240 may be coupled to the drain terminal of the amplifier 210, the second terminal of the resistor 240 may be coupled to one terminal of the inductor 250, and the other terminal of the inductor 250 may be coupled to a supply voltage. The inductors 250 may be coupled inductors.

FIG. 2B illustrates an electric circuit diagram of an AFE component 200B, according to an embodiment. The AFE component 200B may be an example of the AFE 114 and the AFE 142 (or a part thereof), or may be a part of an AFE stage of a communication system other than an optical communication system or may be part of an AFE stage of a system other than a communication system. The AFE component 200B is similar to the AFE component 200A except that it further includes a capacitor 260 coupled to the second terminals of the inductors 220 in each of the signal branches 202, each capacitor 260 denoted in FIG. 2B with a letter “n” after the reference numeral for the negative signal branch 202n and with a letter “p” after the reference numeral for the positive signal branch 202p. As shown in FIG. 2B, in some embodiments, the first terminal of the capacitor 260n may be coupled to terminal N2 of the inductor 220n and to the drain terminal of the current source 230n, the first terminal of the capacitor 260p may be coupled to terminal P2 of the inductor 220p and to the drain terminal of the current source 230p, and the second terminals of the capacitors 260n and 260p may be coupled to ground. In some embodiments, the capacitors 260 may be tunable capacitors. Implementing capacitors 260 coupled to the second terminals of the inductors 220 may enable resonance at the desired frequency with smaller inductance values for inductors 220. By reducing the required inductance, the physical footprint of the inductors 220 can be decreased, which is advantageous for minimizing die area and overall layout complexity. Smaller inductors also exhibit lower parasitic resistance and capacitance, thereby improving quality factor (Q) and reducing unwanted signal loss or distortion. In addition, inductors 220 with lower inductance values are generally easier to design and implement within standard IC process constraints, further simplifying integration of the inductors 220 into the AFE component 200B.

FIG. 2C illustrates an electric circuit diagram of an AFE component 200C, according to an embodiment. The AFE component 200C may be an example of the AFE 114 and the AFE 142 (or a part thereof), or may be a part of an AFE stage of a communication system other than an optical communication system or may be part of an AFE stage of a system other than a communication system. The AFE component 200C is similar to the AFE component 200A except that it further includes a capacitor 270 coupled to the second terminals of the inductors 220 in each of the signal branches 202, each capacitor 270 denoted in FIG. 2C with a letter “n” after the reference numeral for the negative signal branch 202n and with a letter “p” after the reference numeral for the positive signal branch 202p. As shown in FIG. 2C, in some embodiments, the first terminal of the capacitor 270n may be coupled to terminal N2 of the inductor 220n and to the drain terminal of the current source 230n, the first terminal of the capacitor 270p may be coupled to terminal P2 of the inductor 220p and to the drain terminal of the current source 230p, and the second terminals of the capacitors 270n and 270p may be coupled to ground. In some embodiments, the capacitors 270 may be tunable capacitors. The capacitors 270 may be similar to the capacitors 260 of the AFE component 200B, except that the capacitors 270 may be used to increase drain capacitance loading the coils of the inductors 220, which may be advantageous in terms of, e.g., suppressing unwanted high-frequency components or providing an additional degree of impedance matching.

FIG. 2D illustrates an electric circuit diagram of an AFE component 200D, according to an embodiment. The AFE component 200D may be an example of the AFE 114 and the AFE 142 (or a part thereof), or may be a part of an AFE stage of a communication system other than an optical communication system or may be part of an AFE stage of a system other than a communication system. The AFE component 200D is similar to the AFE component 200B in that it includes capacitors 260 as described with reference to FIG. 2B, and is further similar to the AFE component 200C in that it includes capacitors 270 as described with reference to FIG. 2C.

FIGS. 3A-3C illustrate how positive coupling between inductors 220 may be achieved, according to an embodiment.

FIG. 3A illustrates portions of the signal branches 202 that include inductors 220 as described with reference to FIGS. 2A-2D. Terminals N1, N2, P1, and P2 are identified in FIG. 3A in the same manner as in FIGS. 2A-2D.

FIG. 3B illustrates that each of the inductors 220 may be implemented as a conductive contour extending, continuously, from the first terminal to the second terminal of the inductor. Thus, inductor 220n may include a first conductive contour extending from terminal N1 to terminal N2, while inductor 220p may include a second conductive contour extending from terminal P1 to terminal P2. In an IC structure, such conductive contours may be realized as any suitable combination of metal traces and vias distributed across different layers of a metallization stack. The relative layout of inductors 220 shown in FIG. 3B is not representative of an actual IC arrangement, since the inductors in this example do not overlap and would therefore exhibit a prohibitively small coupling coefficient. By contrast, FIG. 3C illustrates an example in which the inductors 220 are arranged so that their conductive contours at least partially overlap one another in projection, without forming direct electrical contact. More specifically, for the inductors 220 to be coupled, a projection of at least a portion of the conductive contour of inductor 220n onto a plane parallel to the die on which the AFE component 200 is implemented overlaps with a projection of at least a portion of the conductive contour of inductor 220p onto that same plane.

Returning to FIG. 3B, which provides more space for illustrating current flow directions, arrow 302n indicates the direction of current through inductor 220n and arrow 302p indicates the direction of current through inductor 220p. As shown, the inductors 220 may be arranged such that the current in both inductors flows in the same direction. In the illustrated example, both flow counterclockwise, though in other embodiments both may flow clockwise. This arrangement may be achieved by incorporating a crossing 310 in the conductive contour of one inductor 220 while omitting such a crossing in the other. In the example of FIG. 3B, crossing 310 is present in inductor 220n, while inductor 220p has no crossing; however, the opposite configuration may also be used. Crossing 310 indicates that a conductive contour of one inductor 220 (e.g., of the inductor 220n) includes a first metal trace and a second metal trace located in different metallization layers, which, when projected onto a plane parallel to the die, form an x-shape. By contrast, no two traces of the conductive contour of the other inductor 220 (e.g., of the inductor 220p) would form such an x-shape in projection.

Providing a crossing 310 in one inductor 220 but not the other ensures that both inductors 220 are wound in the same direction, which in turn results in a positive coupling coefficient between the inductors 220. In particular, the presence of the crossing 310 causes one portion of the conductive contour to be routed over a different metallization layer and to intersect another portion of the contour in projection, thereby reversing the apparent winding sense that would otherwise result if the inductor were implemented without the crossing. By including the crossing in only one of the inductors 220, both inductors can be made to exhibit the same overall winding orientation (e.g., both counterclockwise or both clockwise when viewed in projection onto a plane parallel to the die). This alignment of winding direction ensures that the magnetic flux generated by current flowing in one inductor reinforces, rather than cancels, the magnetic flux generated in the other inductor. As a result, the mutual inductance M between the inductors is positive, and the coupling coefficient k is likewise positive. In contrast, if the inductors were wound in opposite directions (e.g., with no crossing provided in either contour or with crossings provided in both contours), the induced magnetic fluxes would oppose one another, leading to negative mutual inductance and a negative coupling coefficient. Thus, selectively implementing a crossing 310 provides a straightforward structural mechanism to achieve a positive coupling coefficient, which is advantageous for maintaining a high common-mode inductance while minimizing differential-mode inductance, as discussed above.

FIG. 4 illustrates a top-down view of an IC structure 400, showing an example layout of metal traces in different layers of a metallization stack to realize a positively coupled inductor arrangement, according to an embodiment. As shown in FIG. 4, the IC structure 400 may be provided over a support 401 and include a plurality of metal traces forming the inductors 220n and 220p as described herein. In some embodiments, the support 401 may include a semiconductor die, a substrate, a wafer, or a chip, and may be formed from materials such as silicon, silicon-on-insulator (SOI), III-V semiconductors, glass, or other suitable materials. Metal traces in different layers above the support 401 are shown in FIG. 4 with different colors of patterns. Metal traces that are provided in different layers above the support but at least partially overlap with one another in their footprint with respect to the support 401 are shown in FIG. 4 as overlaying one another. Metal vias that make electrical connections between metal traces in different layers are shown in FIG. 4 as circles. In some embodiments, metal traces of the IC structure 400 may be implemented in various layers of a metallization stack of the IC structure 400, e.g., provided in back-end-of-line (BEOL) portion of the IC structure 400. On the other hand, the amplifiers 210 may be implemented in front-end-of-line (FEOL) portion of the IC structure 400, i.e., closer to the support 401 than the metal traces forming the inductors 220.

The inductor 220n is illustrated in FIG. 4 as a collection of metal traces over which solid arrows are shown, the arrows indicating the direction of the current flow from terminal N1 to terminal N2. A collection of solid arrows shown in FIG. 4 is similar to the arrow 302n, shown in FIG. 3B. The inductor 220p is illustrated in FIG. 4 as a collection of metal traces over which dashed arrows are shown, the arrows indicating the direction of the current flow from terminal P1 to terminal P2. A collection of dashed arrows shown in FIG. 4 is similar to the arrow 302p, shown in FIG. 3B.

As shown in FIG. 4, the inductor 220n may include metal traces 402, 404, 406, 408, 410, 412, 414, 416, 418, and 420 that together form an electrically continuous conductive contour. The metal traces 402, 404, 406, 408, and 410 may be metal traces provided in a single layer (i.e., may be coplanar) above the support 401, as shown in FIG. 4 with these metal traces having the same pattern. Similarly, the metal traces 412, 414, 416, 418, and 420 may be metal traces provided in a single layer above the support 401, as shown in FIG. 4 with these metal traces having the same color, but the layer of the metal traces 412, 414, 416, 418, and 420 is different (e.g., above or below) the layer of the metal traces 402, 404, 406, 408, and 410. To that end, a via 430 is shown in FIG. 4, indicating a transition from the metal trace 410 to the metal trace 412 (e.g., thus, one end of the via 430 may be conductively coupled to an end of the metal trace 410 and another end of the via 430 may be conductively coupled to an end of the metal trace 420).

As further shown in FIG. 4, the inductor 220p may include metal traces 432, 434, 436, 438, 440, 442, 444, 446, 448, 450, 452, and 454 that together form an electrically continuous conductive contour. The metal traces 432, 434, 436, 438, 440, and 442 may be metal traces provided in a single layer above the support 401, as shown in FIG. 4 with these metal traces having the same pattern. In some embodiments, this layer may be the same layer in which the metal traces 402, 404, 406, 408, and 410 of the inductor 220n are provided, as indicated in FIG. 4 with the metal traces 432, 434, 436, 438, 440, and 442 having the same pattern as the metal traces 402, 404, 406, 408, and 410. However, in other embodiments, the metal traces 432, 434, 436, 438, 440, and 442 and the metal traces 402, 404, 406, 408, and 410 may be provided in different layers above the support 401. As also shown in FIG. 4, the metal traces 444, 446, 448, 450, 452, and 454 may be metal traces provided in a single layer above the support 401, as shown in FIG. 4 with these metal traces having the same color, but the layer of the metal traces 444, 446, 448, 450, 452, and 454 is different from (e.g., above or below) the layer of the metal traces 432, 434, 436, 438, 440, and 442. To that end, a via 460 is shown in FIG. 4, indicating a transition from the metal trace 442 to the metal trace 444 (e.g., thus, one end of the via 460 may be conductively coupled to an end of the metal trace 442 and another end of the via 460 may be conductively coupled to an end of the metal trace 444). Although the metal traces 444, 446, 448, 450, 452, and 454 of the inductor 220p and the metal traces 412, 414, 416, 418, and 420 of the inductor 220n are shown in FIG. 4 with different colors, in some embodiments, they may be implemented in a single layer.

FIG. 4 illustrates that, in some embodiments, projections onto a plane parallel to the support 401 of the portions of the metal trace 414 of the inductor 220n and the metal trace 440 of the inductor 220p may overlap. Similarly, projections of the portions of the metal trace 408 of the inductor 220n and the metal trace 446 of the inductor 220p may overlap. Such overlap may help increase the coupling coefficient between the inductors 220 since alignment of portions of the inductors 220 allows increasing overlapping magnetic flux. FIG. 4 further illustrates the crossing 310 as in FIG. 3B. Similar to the description of FIG. 3B, in the IC structure 400, the crossing 310 indicates that the conductive contour of the inductor 220n includes the metal trace 404 and the metal trace 418 located in different metallization layers, which, when projected onto a plane parallel to the support 401, form an x-shape. By contrast, no two metal traces of the conductive contour of the inductor 220p of the IC structure 400 would form such an x-shape in projection. While the arrangement of the metal traces of the inductor 220p shown on the right side of FIG. 4 (within a dashed box 470) seems to show an x-shape, there are no two metal traces there that form the x-shape. In the box 470, the metal traces 434 and 436 form a v-shape in one plane above the support 401, and the metal traces 450 and 452 form another v-shape in another plane above the support 401, but no single pair of the metal traces 434, 436, 450, and 452 form an x-shape when they are projected onto a single plane parallel to the support 401, in contrast to the metal traces 404 and 418 of the inductor 220n. Thus, the IC structure 400 provides one example illustration how a positive coupling coefficient of the inductors 220 may be achieved in an IC device. Other implementations of IC structures that ensure positive coupling coefficient of the inductors 220 are possible and are within the scope of the present disclosure.

The following paragraphs provide examples of various ones of the embodiments disclosed herein.
Example 1 provides an AFE component (e.g., a CTLE), the AFE component including a first signal branch including a first amplifier and a first inductor; and a second signal branch including a second amplifier and a second inductor, in which: one of the first signal branch and the second signal branch is a positive signal branch of a differential circuit, another one of the first signal branch and the second signal branch is a negative signal branch of the differential circuit, and the first inductor and the second inductor have a positive coupling coefficient.
Example 2 provides the AFE component according to example 1, in which: the first amplifier includes a first transistor, the second amplifier includes a second transistor, the first inductor is coupled to a source terminal of the first transistor, and the second inductor is coupled to a source terminal of the second transistor.
Example 3 provides the AFE component according to example 2, further including a resistor coupled between the source terminal of the first transistor and the source terminal of the second transistor.
Example 4 provides the AFE component according to example 3, further including a capacitor coupled between the source terminal of the first transistor and the source terminal of the second transistor.
Example 5 provides the AFE component according to example 4, in which at least one of the resistor and the capacitor is tunable.
Example 6 provides the AFE component according to any one of examples 2-5, further including a first current source; and a second current source, in which: a first terminal of the first inductor is coupled to the source terminal of the first transistor, a second terminal of the first inductor is coupled to the first current source, a first terminal of the second inductor is coupled to the source terminal of the second transistor, and a second terminal of the second inductor is coupled to the second current source.
Example 7 provides the AFE component according to example 6, further including a first capacitor having a terminal coupled to the second terminal of the first inductor and to the first current source; and a second capacitor having a terminal coupled to the second terminal of the second inductor and to the second current source.
Example 8 provides the AFE component according to example 7, further including a third capacitor having a terminal coupled to the second terminal of the first inductor and to the first current source; and a fourth capacitor having a terminal coupled to the second terminal of the second inductor and to the second current source.
Example 9 provides the AFE component according to any one of examples 2-8, in which: the AFE component includes a first input terminal and a second input terminal, the first input terminal is coupled to a gate terminal of the first transistor, and the second input terminal is coupled to a gate terminal of the second transistor.
Example 10 provides the AFE component according to any one of examples 2-9, in which: the AFE component includes a first output terminal and a second output terminal, the first output terminal is coupled to a drain terminal of the first transistor, and the second output terminal is coupled to a drain terminal of the second transistor.
Example 11 provides the AFE component according to example 10, in which: the first signal branch further includes a first resistor coupled to the first output terminal and the drain terminal of the first transistor, and the second signal branch further includes a second resistor coupled to the second output terminal and the drain terminal of the second transistor.
Example 12 provides the AFE component according to example 11, in which: the first signal branch further includes an additional inductor coupled in series with the first resistor, and the second signal branch further includes an additional inductor coupled in series with the second resistor.
Example 13 provides the AFE component according to any one of examples 1-12, in which: the first amplifier is a first common-source amplifier, and the second amplifier is a second common-source amplifier.
Example 14 provides the AFE component according to any one of examples 1-13, further including a substrate; and a plurality of layers stacked over the substrate, in which: the plurality of layers include one or more dielectric materials, the first inductor includes a first metal line in a first layer of the plurality of layers and a second metal line in a second layer of the plurality of layers, and a projection of the first metal line onto a plane parallel to the substrate intersects with a projection of the second metal line onto the plane parallel to the substrate.
Example 15 provides the AFE component according to any one of examples 1-14, in which the first inductor and the second inductor are arranged so that, during operation of the AFE component, a direction of current flow in the first inductor is same as a direction of current flow in the second inductor.
Example 16 provides an AFE component, the AFE component including a differential circuit having a negative signal branch and a positive signal branch, in which: the negative signal branch includes a first input transistor and a first inductor coupled to a source terminal of the first input transistor, the positive signal branch includes a second input transistor and a second inductor coupled to a source terminal of the second input transistor, and a coupling coefficient of the first inductor and the second inductor is positive and greater than a threshold value.
Example 17 provides the AFE component according to example 16, in which, during operation of the AFE component, a direction of current flow in the first inductor is same as a direction of current flow in the second inductor.
Example 18 provides an electronic component, including a die; and an amplifier stage including a first input and a second input, a first output and a second output, a first amplifier and a second amplifier over the die, in which a first terminal of the first amplifier is coupled to the first input, a second terminal of the first amplifier is coupled to the first output, a first terminal of the second amplifier is coupled to the second input, and a second terminal of the second amplifier is coupled to the second output, a first inductor coupled to a third terminal of the first amplifier, and a second inductor coupled to a third terminal of the second amplifier, in which, during operation of the AFE component, a direction of current flow in the first inductor is same as a direction of current flow in the second inductor.
Example 19 provides the electronic component according to example 18, in which: the first amplifier is a first common-source amplifier, and the second amplifier is a second common-source amplifier.
Example 20 provides the electronic component according to examples 18 or 19, in which the first inductor and the second inductor are positively coupled inductors.
Example 21 provides an electronic component for amplifying a differential signal, the electronic component including a negative signal branch including a first transistor and a first inductor coupled to a source terminal of the first transistor; a positive signal branch including a second transistor and a second inductor coupled to a source terminal of the second transistor; and a circuit including a resistor and a capacitor in parallel coupled between the source terminal of the first transistor and the source terminal of the second transistor, in which, during operation of the electronic component, the first inductor and the second inductor are positively coupled inductors.
Example 22 provides the electronic component according to example 21, in which an arrangement of the first inductor and an arrangement of the second inductor is such that, during operation of the electronic component: directions of current flow in the first inductor and the second inductor are both counterclockwise, or directions of current flow in the first inductor and the second inductor are both clockwise.
Example 23 provides the electronic component according to example 22, in which: the arrangement of the first inductor includes a shape and a winding direction of the first inductor, and the arrangement of the second inductor includes a shape and a winding direction of the second inductor.
Example 24 provides an integrated circuit (IC) structure, including a die; a first amplifier and a second amplifier over the die; and a first inductor and a second inductor over the die, in which: the first inductor includes a first conductive contour, the second inductor includes a second conductive contour, a projection of a first portion of the first conductive contour onto a plane parallel to the die at least partially overlaps with a projection of a first portion of the second conductive contour onto the plane, the first portion of the first conductive contour and the first portion of the second conductive contour are in different layers over the die, the first conductive contour includes a first metal trace and a second metal trace in different layers over the die, when projected on the plane, the first metal trace and the second metal trace form an x-shape, and no two metal traces of the second conductive contour form the x-shape.
Example 25 provides the IC structure according to example 24, in which: the first amplifier includes a first transistor having a channel portion in a first portion of a semiconductor material of the die, the second amplifier includes a second transistor having a channel portion in a second portion of the semiconductor material of the die, and each of the first conductive contour and the second conductive contour has portions in different layers of a dielectric material over the semiconductor material of the die.
Example 26 provides the IC structure according to example 24, in which: the first amplifier includes a first transistor, the second amplifier includes a second transistor, the first inductor is coupled to a source terminal of the first transistor, and the second inductor is coupled to a source terminal of the second transistor.
Example 27 provides the IC structure according to example 26, further including a resistor coupled between the source terminal of the first transistor and the source terminal of the second transistor.
Example 28 provides the IC structure according to example 28, further including a capacitor coupled in electrical parallel with the resistor.
Example 29 provides the IC structure according to examples 26-28, further including a first current source; and a second current source, in which: a first terminal of the first inductor is coupled to the source terminal of the first transistor, a second terminal of the first inductor is coupled to the first current source, a first terminal of the second inductor is coupled to the source terminal of the second transistor, and a second terminal of the second inductor is coupled to the second current source.
Example 30 provides the IC structure according to example 29, further including a first capacitor having a terminal coupled to the second terminal of the first inductor and to the first current source; and a second capacitor having a terminal coupled to the second terminal of the second inductor and to the second current source.
Example 31 provides an electronic component including an AFE stage, in which the AFE stage includes an AFE component according to any one of examples 1-17 or an electronic component according to any one of claims 18-23 or an IC structure according to any one of claims 24-30.
Example 32 provides the electronic component according to example 31, further including digital signal processing (DSP) circuitry.
Example 33 provides the electronic component according to example 32, in which the AFE stage and the DSP circuitry are on a single die.
Example 34 provides the electronic component according to any one of examples 31-33, further including an ADC.
Example 35 provides the electronic component according to example 34, in which the AFE stage and the ADC are on a single die.
Example 36 provides the electronic component according to any one of examples 31-35, further including a DAC.
Example 37 provides the electronic component according to example 36, in which the AFE stage and the DAC are on a single die.
Example 38 provides the electronic component according to any one of examples 31-37, in which the electronic component is an optical transmitter of an optical communication system.
Example 39 provides the electronic component according to any one of examples 31-37, in which the electronic component is an optical receiver of an optical communication system.
Example 40 provides the electronic component according to any one of examples 31-39, in which the electronic component is part of an optical interconnect system.
Example 41 provides the electronic component according to any one of examples 31-37, in which the electronic component is an RF transmitter of an RF communication system.
Example 42 provides the electronic component according to any one of examples 31-37, in which the electronic component is an RF receiver of an RF communication system.
Example 43 provides the electronic component according to any one of examples 31-37, in which the electronic component is an RF transmitter of a LiDAR system.
Example 44 provides the electronic component according to any one of examples 31-37, in which the electronic component is an RF receiver of a LiDAR system.
Example 45 provides the electronic component according to any one of examples 31-37, in which the electronic component is part of a LiDAR system.
Example 46 provides the electronic component according to any one of examples 31-37, in which the electronic component is part of an automotive system.
Example 47 provides the electronic component according to any one of examples 31-37, in which the electronic component is part of a medical device.
Example 48 provides the electronic component according to any one of examples 31-37, in which the electronic component is an RF transmitter of a consumer electronics device.
Example 49 provides the electronic component according to any one of examples 31-37, in which the electronic component is an RF receiver of a consumer electronics device.
Example 50 provides the electronic component according to any one of examples 48-49, in which the consumer electronics device is one of a mobile phone, a tablet, a smart watch, or a laptop.

The foregoing description of the illustrated embodiments, including the Abstract, is provided for illustrative purposes and is not intended to be exhaustive or to restrict the disclosure to the specific implementations shown. Although particular examples and embodiments are described herein, those skilled in the relevant art will recognize that numerous variations, modifications, and equivalent implementations are possible within the scope of the disclosure. Such modifications may be made in light of the detailed description provided above, without departing from the principles and spirit of the disclosure.

1. An analog front-end (AFE) component, the AFE component comprising:
a first signal branch comprising a first amplifier and a first inductor; and
a second signal branch comprising a second amplifier and a second inductor,
wherein:
one of the first signal branch and the second signal branch is a positive signal branch of a differential circuit,
another one of the first signal branch and the second signal branch is a negative signal branch of the differential circuit, and
the first inductor and the second inductor have a positive coupling coefficient.

2. The AFE component according to claim 1, wherein:
the first amplifier includes a first transistor,
the second amplifier includes a second transistor,
the first inductor is coupled to a source terminal of the first transistor, and
the second inductor is coupled to a source terminal of the second transistor.

3. The AFE component according to claim 2, further comprising:
a resistor coupled between the source terminal of the first transistor and the source terminal of the second transistor.

4. The AFE component according to claim 3, further comprising:
a capacitor coupled between the source terminal of the first transistor and the source terminal of the second transistor.

5. The AFE component according to claim 4, wherein at least one of the resistor and the capacitor is tunable.

6. The AFE component according to claim 2, further comprising:
a first current source; and
a second current source,
wherein:
a first terminal of the first inductor is coupled to the source terminal of the first transistor,
a second terminal of the first inductor is coupled to the first current source,
a first terminal of the second inductor is coupled to the source terminal of the second transistor, and
a second terminal of the second inductor is coupled to the second current source.

7. The AFE component according to claim 6, further comprising:
a first capacitor having a terminal coupled to the second terminal of the first inductor and to the first current source; and
a second capacitor having a terminal coupled to the second terminal of the second inductor and to the second current source.

8. The AFE component according to claim 7, further comprising:
a third capacitor having a terminal coupled to the second terminal of the first inductor and to the first current source; and
a fourth capacitor having a terminal coupled to the second terminal of the second inductor and to the second current source.

9. The AFE component according to claim 2, wherein:
the AFE component includes a first input terminal and a second input terminal,
the first input terminal is coupled to a gate terminal of the first transistor, and
the second input terminal is coupled to a gate terminal of the second transistor.

10. The AFE component according to claim 2, wherein:
the AFE component includes a first output terminal and a second output terminal,
the first output terminal is coupled to a drain terminal of the first transistor, and
the second output terminal is coupled to a drain terminal of the second transistor.

11. The AFE component according to claim 10, wherein:
the first signal branch further includes a first resistor coupled to the first output terminal and the drain terminal of the first transistor, and
the second signal branch further includes a second resistor coupled to the second output terminal and the drain terminal of the second transistor.

12. The AFE component according to claim 11, wherein:
the first signal branch further includes an additional inductor coupled in series with the first resistor, and
the second signal branch further includes an additional inductor coupled in series with the second resistor.

13. The AFE component according to claim 1, wherein:
the first amplifier is a first common-source amplifier, and
the second amplifier is a second common-source amplifier.

14. The AFE component according to claim 1, further comprising:
a substrate; and
a plurality of layers stacked over the substrate,
wherein:
the plurality of layers include one or more dielectric materials,
the first inductor includes a first metal line in a first layer of the plurality of layers and a second metal line in a second layer of the plurality of layers, and
a projection of the first metal line onto a plane parallel to the substrate intersects with a projection of the second metal line onto the plane parallel to the substrate.

15. The AFE component according to claim 1, wherein the first inductor and the second inductor are arranged so that, during operation of the AFE component, a direction of current flow in the first inductor is same as a direction of current flow in the second inductor.

16. The AFE component according to claim 1, wherein the AFE component is a Continuous-Time Linear Equalizer.

17. An electronic component for amplifying a differential signal, the electronic component comprising:
a negative signal branch comprising a first transistor and a first inductor coupled to a source terminal of the first transistor;
a positive signal branch comprising a second transistor and a second inductor coupled to a source terminal of the second transistor; and
a circuit comprising a resistor and a capacitor in parallel coupled between the source terminal of the first transistor and the source terminal of the second transistor,
wherein, during operation of the electronic component, the first inductor and the second inductor are positively coupled inductors.

18. The electronic component according to claim 17, wherein an arrangement of the first inductor and an arrangement of the second inductor is such that, during operation of the electronic component:
directions of current flow in the first inductor and the second inductor are both counterclockwise, or
directions of current flow in the first inductor and the second inductor are both clockwise.

19. The electronic component according to claim 18, wherein:
the arrangement of the first inductor includes a shape and a winding direction of the first inductor, and
the arrangement of the second inductor includes a shape and a winding direction of the second inductor.

20. An integrated circuit (IC) structure, comprising:
a die;
a first amplifier and a second amplifier over the die; and
a first inductor and a second inductor over the die,
wherein:
the first inductor includes a first conductive contour,
the second inductor includes a second conductive contour,
a projection of a first portion of the first conductive contour onto a plane parallel to the die at least partially overlaps with a projection of a first portion of the second conductive contour onto the plane,
the first portion of the first conductive contour and the first portion of the second conductive contour are in different layers over the die,
the first conductive contour includes a first metal trace and a second metal trace in different layers over the die,
when projected on the plane, the first metal trace and the second metal trace form an x-shape, and no two metal traces of the second conductive contour form the x-shape.

21. The IC structure according to claim 20, wherein:
the first amplifier includes a first transistor having a channel portion in a first portion of a semiconductor material of the die,
the second amplifier includes a second transistor having a channel portion in a second portion of the semiconductor material of the die, and
each of the first conductive contour and the second conductive contour has portions in different layers of a dielectric material over the semiconductor material of the die.
